(19) United States
(12) Patent Application Publication
(10) Pub. No.: US 2026/0106590 A1
(43) Pub. Date: Apr. 16, 2026

(54) Circuitry for and Methods of Gain Control

(71) Applicant: Cirrus Logic International Semiconductor Ltd., Edinburgh (GB)

(72) Inventors: Gary WONG, Edinburgh (GB); John B. BOWLERWELL, Dunfermline (GB); Andrew J. HOWLETT, Edinburgh (GB); Michael CHANDLER-PAGE, Newbury (GB); Jonathan TAYLOR, London (GB); David P. SINGLETON, Edinburgh (GB); Dipankar NAG, Newbury (GB)

(73) Assignee: Cirrus Logic International Semiconductor Ltd., Edinburgh (GB)

(21) Appl. No.: 19/328,496

(22) Filed: Sep. 15, 2025

Related U.S. Application Data
(60) Provisional application No. 63/706,223, filed on Oct. 11, 2024.

(51) Int. Cl. H03G 3/00; H03F 3/187; H03G 3/30

(52) U.S. Cl. CPC H03G 3/001; H03F 3/187; H03G 3/008; H03G 3/3031; H03G 3/3089; H03G 2201/103

(57) ABSTRACT

An integrated circuit (IC), comprising: a first gain stage configured to apply a first gain to a first signal to generate a first gain adjusted signal; a first converter configured to convert the first gain adjusted signal to a first converted signal; a second gain stage configured to apply a second gain to the first converted signal to generate a second gain adjusted signal; and a controller configured to coordinate changes in a first gain of the first gain stage and a second gain of the second gain stage to prevent transients in the second gain adjusted signal.

### TECHNICAL FIELD

The present disclosure relates apparatus, systems and methods of gain control.

### BACKGROUND

Gain control circuits are widely used to vary the gain of signals from various sources. Such gain control circuits may be implemented as part of a signal chain which may include a converter, such as an analog-to-digital converter (ADC), to convert an analog input signal to a digital output signal, or digital-to-analog converter (DAC) to convert a digital input signal to an analog output signal. Such an implementation can be found, for example, in a typical audio mixing desk, to control the volume level of a signal received from an analog source (e.g., a microphone or other line-in port), or sent to an analog output device (e.g. a loudspeaker or other line-out port).

A passive attenuation device (PAD) is a common feature found in audio input devices for professional or musical audio applications. The PAD allows for easy attenuation of an input signal, typically by around 20 dB or 40 dB. When a line input is connected and the signal level is too high (or “hot”), engaging the PAD can sufficiently attenuate the signal to avoid clipping in the downstream signal path, thereby preserving audio quality.

### SUMMARY

According to a first aspect of the disclosure there is provided an integrated circuit (IC), comprising: a first gain stage configured to apply a first gain to a first signal to generate a first gain adjusted signal; a first converter configured to convert the first gain adjusted signal to a first converted signal; a second gain stage configured to apply a second gain to the first converted signal to generate a second gain adjusted signal; and a controller configured to coordinate changes in a first gain of the first gain stage and a second gain of the second gain stage to prevent transients in the second gain adjusted signal.

The first signal may comprise an analog signal, the first converter may comprise an analog-to-digital converter (ADC), and the first converted signal may comprise a digital signal.

The ADC may comprise a switch-capacitor array. The first gain stage may comprise a plurality of switched capacitors. The controller may be configured to control the switched capacitors to change the first gain.

The controller may be configured to change the first gain and the second gain in response to a control signal to implement a total gain.

The controller may be configured to output a control signal via a pin of the IC to adjust an external gain of an external gain stage contributing to the total gain. The controller may be configured to coordinate changes in the external gain to prevent transients in the second gain adjusted signal.

The control circuitry may comprise zero-cross detection circuitry configured to monitor the first signal, the first gain adjusted signal, the first converted signal, or the second gain adjusted signal for a zero-crossing and time-align changes in the first and second gain with the zero-crossing.

The controller may be further configured to output an external gain control signal to a control pin of the IC, the external gain control signal coordinated with changes in the first and second gains.

The controller may be configured to coordinate the changes in the first and second gains using hysteretic control.

The controller may be configured to monitor a signal level of the first converted signal and adjust the first and/or second gain if the signal level exceeds a predetermined threshold level.

The controller may be configured to reverse the adjustment in the first and/or second gain in response to one or more of the following: expiry of a predetermined time period; an external reset command.

The controller may be configured to adjust the first and/or second gain to prevent saturation of the converter whilst maximizing dynamic range in the converter.

According to another aspect of the disclosure, there is provided a system comprising: an IC as described above; and a pre-gain stage configured to apply an attenuation to an input signal to generate the first signal.

The attenuation applied by the pre-gain stage may be fixed.

According to another aspect of the disclosure, there is provided an integrated circuit (IC) comprising: an input for receive an input signal; a converter configured to convert the input signal to a digital signal; a digital gain stage configured to apply a digital gain to the digital signal to generate an output signal; and a controller configured to receive a PAD control signal and a separate gain control signal and adjust operation of the digital gain stage based on the PAD control signal and the gain control signal.

The IC may further comprise an analog gain stage configured to apply an analog gain to the input signal before conversion by the converter. The analog gain may be fixed. Alternatively, the analog gain may be variable. The controller may be configured to adjust operation of the analog gain stage based on the PAD control signal and the gain control signal.

The controller may be configured to output a PAD output signal to an output pin of the IC based on a PAD control signal received at the controller, the PAD output signal for control of an external passive attenuation device coupled to the input.

The controller may be configured to coordinate output of the output signal with changes in the digital gain to prevent transients in the output signal.

The controller may comprise zero-cross detection circuitry for detecting one or more zero-cross events in the signal chain. The controller may be configured to coordinate changes in the digital gain with one of the one or more detected zero-cross events.

The controller may be configured to mute the output signal when changing the digital gain applied to the digital signal.

The input signal may comprise an audio signal.

According to another aspect of the disclosure, there is provided an integrated circuit (IC), comprising: an input for receiving an input signal; a converter configured to convert the input signal to a digital signal; a digital gain stage configured to apply a gain to the digital signal to generate an output signal; and a controller configured to receive a passive attenuation device (PAD) control signal and adjust operation of the digital gain stage in dependence on the PAD control signal.

According to another aspect of the disclosure, there is provided an audio system, comprising: an analog input for receiving an analog input signal; a discrete analog gain stage configured to apply a first analog gain to the first analog input signal to generate a first amplified signal; and an IC as described above, the IC configured to receive the first amplified signal as the input signal.

The discrete analog gain may have a fixed gain or a variable gain. The controller may be configured to control the variable gain.

According to another aspect of the disclosure, there is provided an electronic device comprising the IC system or audio system described above.

The electronic device may comprise a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device, a mixing console, an audio mixing device, an audio recording device, a paging station, an audio input device for use with a computer, a musical instrument, an audio effects processor, an audio surveillance device, a voice capture device, an audio broadcast device, a sound reinforcement device, a wireless electrical musical instrument interface, a wireless microphone, a microphone with digital output, an ultrasound sensing device, an ultrasound recording device, or a sonar device.

Throughout this specification the word “comprise”, or variations such as “comprises” or “comprising”, will be understood to imply the inclusion of a stated element, integer or step, or group of elements, integers, or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIGS. 1A and 1B are schematic diagrams of prior art signal chains;

FIG. 2 is a schematic diagram of a gain control system according to embodiments of the present disclosure;

FIG. 3 illustrates example gain changes implemented by the system of FIG. 2;

FIG. 4 is a schematic diagram of a gain control system according to embodiments of the present disclosure;

FIG. 5 graphically illustrates dynamic range versus input signal amplitude for different gain control system implementations;

FIG. 6 is a schematic diagram of a gain control system according to embodiments of the present disclosure;

FIG. 7 is a schematic diagram of an example implementation of the switched resistor gain stage of FIG. 6; and

FIG. 8 is a schematic diagram of a gain control system according to embodiments of the present disclosure.

### DESCRIPTION OF EMBODIMENTS

A passive attenuation device (PAD) is a common feature found in audio input devices for professional or musical audio applications. The PAD allows for attenuation of an input signal, typically by around 20 dB or 40 dB, at the press of a button on the input audio device. When a line input is connected and the signal level is too high (or “hot”), engaging the PAD can sufficiently attenuate the signal to avoid clipping in the downstream signal path, thereby preserving audio quality.

As such, PADs are useful for audio input devices which need to support audio inputs of differing magnitudes (e.g. line level vs microphone level).

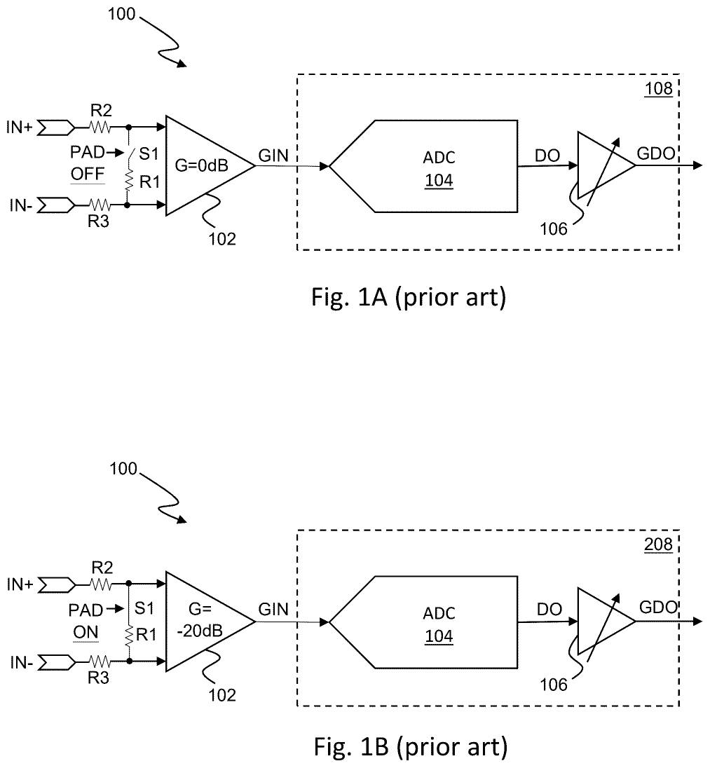

FIGS. 1A and 1B schematically illustrate a typical signal chain 100 for processing an input signal IN in an input audio device.

The signal chain 100 comprises a PAD gain stage 102, an ADC 104, and a digital gain stage 106. In this example, the input signal IN is a differential signal. The ADC 104 and the digital gain stage 106 may be integrated on a single integrated circuit (IC) 108.

The input signal IN is provided to the PAD gain stage 102 which is configured to apply a gain G to the input signal IN and output a first gain adjusted signal GIN to the ADC 104. The ADC 104 is configured to convert the first gain adjusted signal GIN to a digital signal DO which is provided to the digital gain stage 106. The digital gain stage 106 is configured to apply a second gain to the digital signal DO and output a digital gain adjusted signal GDO.

The PAD gain stage 102 may comprise one or more resistors and one or more switches configured to selectively adjust the gain G of the gain stage. In this example, the PAD gain stage 102 comprises a PAD switch S1 coupled in series with a resistor R1. This series combination is coupled between differential inputs IN+, IN− of the PAD gain stage 102 via respective high and low-side input resistors R2, R3. With the PAD switch S1 open as shown in FIG. 1A, the PAD gain stage 102 applies a first gain, e.g. G=0 dB, to the input signal IN. With the PAD switch S1 closed as shown in FIG. 1B, the PAD gain stage 102 applies a second gain, e.g. G=−20 dB, to the input signal IN. The second gain is less than the first gain. For example, the first gain may act to buffer the input signal IN onto the ADC 104 and the second gain may attenuate the input signal IN. Thus, when a line input is connected and the level of the input signal IN is too high, a user can close the PAD switch S1 (e.g. using a button on the input audio device) thereby attenuating the input signal IN so as to avoid clipping in the subsequent signal path (the ADC 104 and/or the digital gain stage 106). In doing so, audio signal quality may be preserved.

For example, the plurality of switches may be configured to switch into the signal chain one or more of the plurality of resistors so as to adjust a resistance in the signal chain between an input and an output of the analog gain stage 102. Additionally, or alternatively, the plurality of switches may be configured to switch resistors into and out of a feedback loop associated with an amplifier of the gain stage 102, thereby altering the gain of that amplifier. The analog gain stage 102 may thus be configured to adjust a gain applied to the signal chain in steps. Such steps are comparatively larger than any steps in resolution of the digital gain stage 110.

An issue with conventional audio PADs, such as those described above, is that transitions in signal gain in response to engagement of a PAD can cause significant and abrupt transitions in the signal chain, such as spikes or sharp drops. Switching of the PAD also leads to a drastic and instantaneous change in input impedance of the gain stage 102. This impedance change momentarily destabilises the amplifier driving the input IN (e.g. an amplifier of a device connected to the input IN). The process by which that amplifier adapts to the new operating point of the signal chain 100 can lead to large transient signals (e.g. “pops”), which not only sound undesirable, but can also cause damage to loudspeakers and human hearing. A further issue with conventional audio PADs is the requirement for an analog switch, which may be expensive to implement.

Embodiments of the present disclosure aim to address or at least ameliorate one or more of the above by implementing smart control of PAD attenuation. For example, a controller may be provided to manage transitions in PAD attenuation so as to reduce or eliminate transients. For example, embodiments of the present disclosure implement control mechanisms to coordinate transitions in analog and digital gain applied to a signal chain with each other as well as with zero-crossing events.

Embodiments of the present disclosure integrate PAD attenuation circuitry with converter and digital gain circuitry. Doing so enables digital control of PAD attenuation, which can be used to avoid or at least ameliorate transients associated with gain changes. Control circuitry may implement zero-cross detection to further minimize transients. Signal level detecting can be used to ensure smooth gain transitions without the introduction of artefacts or distortion in a digital output signal.

In addition to signal monitoring, embodiments incorporate on-chip selectable capacitor ratios for capacitive scaling in ADC sample and hold circuitry, allowing for gain adjustments on-chip.

In addition, embodiments implement gain control after conversion to the digital domain, offering fine gain control resolution between coarser analog gain steps, such as those implemented by PAD attenuation. This digital control mechanism enhances precision of gain-setting and enables smooth changes in signal path gain without abrupt and/or audible glitches due to large step-changes in gain.

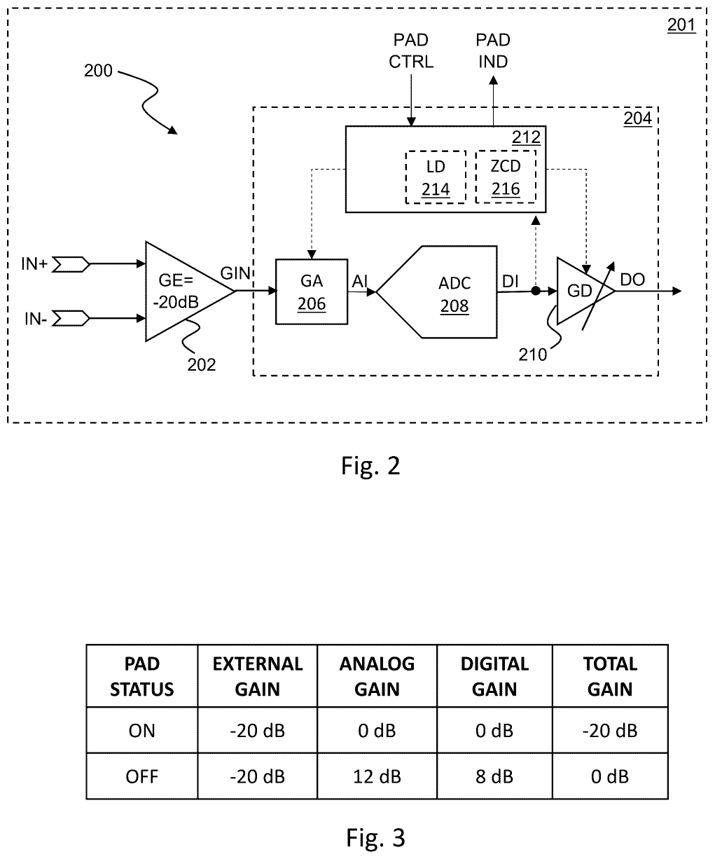

FIG. 2 is a schematic diagram of a PAD system 200 according to embodiments of the present disclosure. The PAD system 200 may be implemented in an input audio device 201.

The PAD system 200 comprises a fixed external gain stage 202 and an IC 204 comprising an analog gain stage 206, an ADC 208, a digital gain stage 210, and a gain controller 212. Whilst the analog gain stage 206 is shown as distinct from the ADC 208, in some embodiments, analog gain may be applied by the ADC 208 such that the analog gain stage 206 is implemented by the ADC 208.

The fixed external gain stage 202 is configured to apply a fixed attenuation (or negative gain G, e.g. G=−20 dB) to an input signal IN received at the input audio device 201. The attenuated signal GIN output from the external gain stage 202 is provided to the analog gain stage 206 which is configured to apply a first internal gain to the attenuated signal GIN to obtain an intermediate signal AI. This intermediate signal AI is provided to the ADC 208, where it is converted into the digital domain to obtain a digital intermediate signal DI. The digital intermediate signal DI is provided to the digital gain stage 210 which is configured to apply a digital gain GD and output a gain adjusted digital output signal DO.

The controller 212 may be configured to control the gain applied by the analog gain stage 206, the digital gain stage 210, or both. The controller 212 may be responsive to a PAD control signal PAD CTRL which may originate from a host device or from the input audio device 201. For example, the input audio device 201 may comprise an external button or switch can be pressed by a user of the input audio device 201 to signal PAD attenuation. Pressing the button or switch may generate or cause a change in the PAD control signal PAD CTRL. The controller 212 may output a PAD indicator signal PAD IND which may be coupled to a status LED (not shown) of the input audio device 201. The PAD indicator signal PAD IND may indicate whether or not PAD attenuation is being applied to the input signal IN, for example by illuminating the status LED.

The fixed external gain stage 202 may be configured to apply a fixed attenuation such that the attenuated signal GIN provided at the input of the ADC 208 is always below a maximum input level of the ADC 208. For example, where a maximum ADC input level of the ADC 208 is 0 dBV, the fixed attenuation may be set to 20 dB (or −20 dB gain). The gain applied by the analog gain stage 206 and the digital gain stage 210 may then be controlled by the controller 212 to maintain a signal level of the intermediate signal AI provided to the ADC 208 within a dynamic range of the ADC 208, whilst providing the necessary signal level in the digital output signal DO output from the digital gain stage 210.

Various regimes may be implemented to maintain these two conditions (a signal level at the input of the ADC 208 within range and a signal level of the digital output signal DO sufficient for further processing).

In some embodiments, the gain of the analog gain stage 206 may be fixed at 0 dB such that the analog gain stage 206 acts as an input buffer to the ADC 208. In such an arrangement, any adjustment in PAD gain is implemented by the digital gain stage 210. The digital gain stage 210 may be configured to apply positive gain up to the value of the negative gain applied by the fixed external gain stage 202. For example, where in fixed external gain stage 202 applies a fixed gain of −20 dB, the digital gain stage 210 may apply a gain of between, e.g. 0 dB and 20 dB.

With such an arrangement, the level of the input signal IN may vary between 0 dBV and 20 dBV. With the input signal IN at 0 dBV, the signal level of the attenuated signal GIN and the intermediate signal SI would be −20 dBV due to attenuation by the fixed external gain stage 202. The controller 212 may control the digital gain stage 210 to apply a gain of 20 dB to increase the signal level of the digital output signal DO. When the level of the input signal IN is at 20 dBV, the signal level of the attenuated signal GIN and the intermediate signal SI would be 0 dBV due to attenuation by the fixed external gain stage 202. The controller 212 may control the digital gain stage 210 to apply a gain of 0 dB, since the level of the digital signal DI output from the ADC 208 is already at 20 dBV.

It will be appreciated that the dynamic range of the signal path in the PAD system 200 of FIG. 2 will suffer at low input signal IN levels due to the fixed attenuation applied by the fixed external gain stage 202.

Accordingly, in some embodiments, the analog gain GA applied by the analog gain stage 206 may be adjustable in addition to the digital gain GD applied by the digital gain stage 210. The controller 212 may be configured to adjust both the analog gain GA and the digital gain GD.

For example, the analog gain stage 206 may be controlled by the controller 212 to adjust a gain applied to the attenuated signal GIN. The controller 212 may control the gain applied by the analog gain stage 206 to maximise a level of the intermediate signal AI provided to the ADC 208 so as to maximise dynamic range whilst preventing clipping in the ADC 208.

Accordingly, when compared to the analog gain stage 206 having a fixed gain of 0 dB, by adapting the analog and digital gain stages 206, 210, dynamic range can be maintained at all signal levels whilst ensuring that clipping does not occur in the ADC 208.

For example, if the fixed external gain GE applied by the external gain stage 202 is −20 dB, then 20 dB of internal gain may be applied in the IC 204 between the analog and digital gain stages 206, 210. For example, the analog gain stage 206 may apply 12 dB of gain, and the digital gain stage 210 may apply 8 dB of gain, the total gain totalling 20 dB. In another example, the analog gain stage 206 may apply 8 dB of gain, and the digital gain stage 210 may apply 12 dB of gain, the total gain totalling 20 dB. The ratio of analog to digital gain may be adjusted to maximize the level of the intermediate signal AI provided to the ADC 208, thereby increasing dynamic range.

Thus, in this hybrid gain implementation, total gain applied by the IC 204 is split between analog and digital gain stages 206, 210.

The controller 212 may control application or analog and digital gain GA, GD in dependence on the PAD control signal PAD CTRL. For example, when the PAD control signal PAD CTRL is asserted, the controller 212 may control the analog and digital gain states 206, 210.

FIG. 3 illustrate an example implementation of PAD control using the analog and digital gain stages 206, 210. When the PAD control signal CTRL is asserted and PAD attenuation is “ON”, the external gain stage 202 applies a gain of −20 dB, and the analog and digital gain stages 206, 210 apply a gain of 0 dB. The total gain of the signal chain is −20 dB. When the PAD control signal CTRL is de-asserted and PAD attenuation is “OFF”, the external gain stage 202 applies a gain of −20 dB, the analog gain stage 206 applies a gain of 12 dB, and the digital gain stage 210 applies a gain of 8 dB. The total combined of the signal chain is 0 dB. The values of gain provided in this example are an example only and other values of gain may be applied. In addition, the distribution of gain applied by the analog and digital gain stages 206, 210 may vary as discussed above.

The distribution of gain may be adjusted in dependence on a level of a signal in the signal chain, such as the gain adjusted input signal GIN, the intermediate signal AI, the digital intermediate signal DI or the digital output signal DO. As such, the controller 212 may comprise level detection (LD) circuitry 214 to monitor such levels. In the example shown in FIG. 2, LD circuitry 214 is configured to monitor a level of the intermediate digital signal DI output from the ADC 208. Additionally, or alternatively, the controller 212 may be configured to monitor one or more levels of the intermediate signal AI, the gain adjusted input signal GIN and/or the digital output signal DO. Based on the one or more detected levels, distribution of gain applied by the analog and digital gain stages 206, 210 may be controlled. This control helps prevent the intermediate signal DI output from the ADC 208 from saturating whilst ensuring optimal performance (e.g. dynamic range) without manual intervention.

For example, consider the scenario where no attenuation is being applied by the digital and analog gain stages 206 210, for example when the PAD control signal PAD CTRL is not asserted and the combined gain of the analog and digital gain stages 206, 210 is 20 dB. If the LD circuitry 214 detects that the ADC output signal reaches or exceeds a threshold level (which may be set to be close to full-scale of the ADC 208) it may signal an out-of-range condition, and the controller 212 may be configured to control logic to perform a switch of the analog and digital gain stages 206 ,210 to apply a gain of 0 dB. This changes in overall gain of the signal path from 0 dB to −20 dB, allows the signal path to accommodate higher input signal levels than before the gain change.

Some applications may require a change in gain applied by the analog and digital gain stages 206, 210 in response to an out-of-range condition to be infrequent. For example, where the LD circuitry 214 detects an out-of-range condition, the controller 212 may be configured to latch the gain to the attenuated state. Doing so may minimise the risk of audible glitches due to multiple (flipflopping) gain change and to be similar to the behaviour expected by a user familiar with a manually operated pad.

Where the controller 212 latches the gain change, one or more methods may be implemented to return the PAD attenuation to an unselected state. For example, the threshold may be a fixed threshold with or without hysteresis. For example, a timer may be implemented such that the controller 212 is configured to revert the gain back to the original non-attenuated state after a predetermined period of time. For example, the controller 212 may be configured to measuring an average energy in a signal, such as a weighted moving integrated average. The average energy may be compared to a threshold for the purpose of changing the gain. For example, the amount of energy in a portion of the signal that exceeds a threshold energy level may be measured and integrated over a set time period, to determine a peak energy level. Optionally, a user of the input audio device 201 may be able to manually disengage PAD attenuation, for example, by operating a switch or button.

It will be appreciated that timing errors in switching of the analog and digital gain stages 206, 210 can lead to discontinuities in the digital output signal DO. To counter such discontinuities, latency compensation delay may be implemented. Specifically, a predetermined delay between activation of gain changes in the analog gain stage 206 and the digital gain stage 210 may be tuned to take into account the combination of latency associated with the ADC 208 and any filters provided in the signal chain between the ADC 208 and the digital gain stage 210. In doing so, the controller 212 can control the digital gain stage 210 gain change to coincide with the signal discontinuity caused by any zero-cross error on the analog gain change implemented by the analog gain stage 206. Such latency compensation is described in detail in U.S. patent applications Ser. No. 17/982,864, Ser. No. 17/983,000, or Ser. No. 18/505,734, the contents of each of which is hereby incorporated by reference in their entirety.

In addition to time aligning gain changes in the signal chain to remove discontinuities with gain misalignment, changes in gain applied by the analog and digital gain stages may be synchronised with one or more signal events in the signal chain, such as zero-crossing events. Such zero-cross alignment is described in detail in U.S. patent applications Ser. No. 17/982,864, Ser. No. 17/983,000, or Ser. No. 18/505,734, the contents of each of which is hereby incorporated by reference in their entirety.

To implement such control, the controller 212 may comprise zero cross detection (ZCD) circuitry 216. The ZCD circuitry 216 may be configured to detect zero crossing in any one or more of the gain adjusted signal GIN, the intermediate signal AI, the intermediate digital signal DI and the digital output signal. The ZCD 216 may output a zero-crossing signal indicating a zero-crossing event in the signal chain. The controller 212 may then be configured to time-align gain changes applied by the analog and digital gain stages 206, 210 with the zero-crossing events occurring at respective analog and digital gain stages 206, 210.

An advantage of the arrangement shown in FIG. 2 is that gain changes can be time-aligned so as to be inaudible or nearly inaudible, compared to the loud and undesirable “pop” noise associated with conventional PADs. In addition, the provision of a digital PAD such as that shown in FIG. 2 may reduce cost when compared to the provision of a conventional analog PAD which requires an analog switch.

The arrangement shown in FIG. 2 may be implemented instead of or in combination with an external PAD.

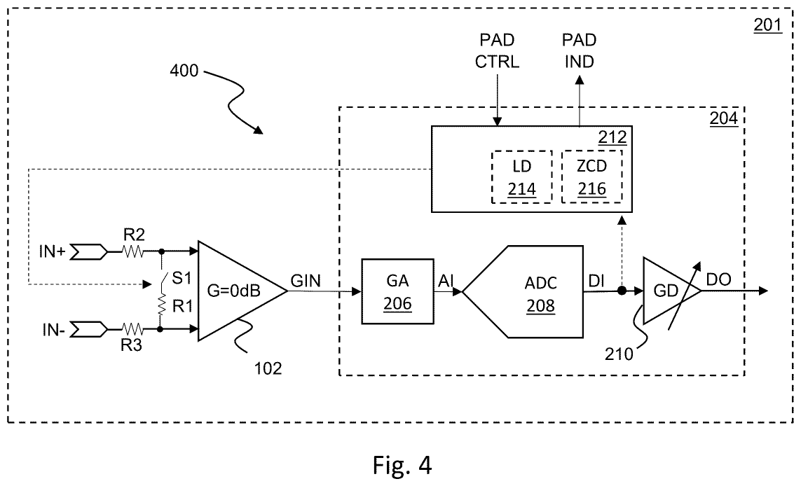

FIG. 4 is a schematic diagram of a PAD system 400 which is a variation of the PAD system 200 of FIG. 2, like parts having like numerals. The PAD system 400 differs from the PAD system in FIG. 4 in that the fixed external gain stage 202 is replaced with the PAD gain stage 102 of FIGS. 1A and 1B and in, instead of controlling the analog and digital gain stages 206, 210, the controller 212 is configured to control the control switch S1 of the PAD gain stage 102. As above, an issue with conventional PAD design is that large gain step changes introduce high-amplitude transient signals (“pops”), which can sound unpleasant and can damage loudspeakers or human hearing. The design shown in FIG. 4 allows a user to manually switch PAD attenuation on or off via a button of the input audio device coupled to the PAD control input of the controller 212. However, in response to an assertion of the PAD control signal PAD CTRL, the controller 212 is configured to manage gain transitions based on zero-crossing. Such control may comprise time aligning switching of the switch S1 and/or muting of the digital output signal DO to block loud “pop” transients. Smooth gain ramping may also be implemented by combining the manual external PAD gain stage 102 with adjustments to the analog gain stage 206 and/or the digital gain stage 210, thereby minimizing audible transients to gain transitions.

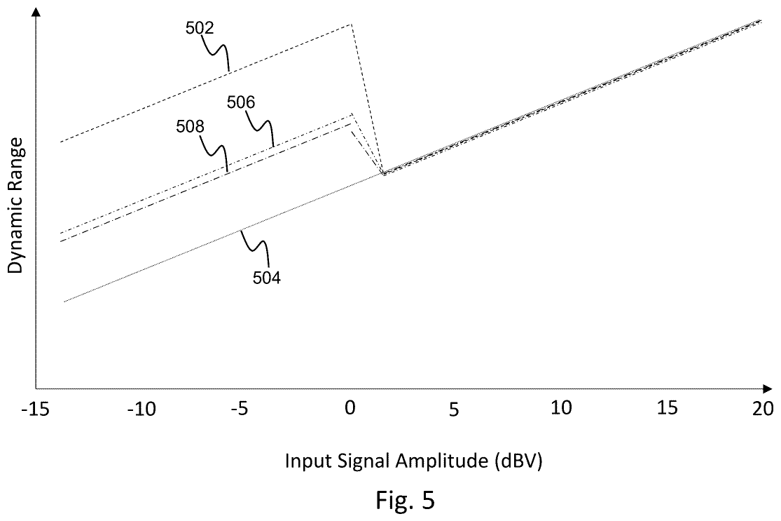

FIG. 5 is a graphical illustration comparing dynamic range (DNR) versus input signal amplitude for the different implementations described above. Line 502 plots DNR vs input signal amplitude for a conventional PAD, such as that shown in FIGS. 1A and 1B. Line 504 plots DNR vs input signal amplitude for purely digital gain as applied, for example, by the digital gain stage 210. It can be seen that the DNR in the digitally applied gain is reduced when compared to conventional PAD attenuation. Line 506 plots DNR vs input signal amplitude for a hybrid gain of 20 dB implemented between the analog and digital gain stages 206, 210 of the PAD system 200 of FIG. 2. Line 508 plots DNR vs input signal amplitude for a hybrid gain of 12 dB implemented between the analog and digital gain stages 206, 210 of the PAD system 200 of FIG. 2. It can be seen that DNR of signals experiencing hybrid gain is increased when compared to purely digital gain and reduced relative to purely analog PAD attenuation as implemented by the arrangement shown in FIGS. 1A and 1B.

As noted above, hybrid gain control (or HGC) systems are used to control digital and analog gain stages, such as can be found in U.S. patent applications Ser. No. 17/982,864, Ser. No. 17/983,000, or Ser. No. 18/505,734, the contents of which are incorporated by reference in their entirety. Such systems provide gain setting control from an ADC integrated circuit (IC) of an external analog gain stage of a conditioning circuit, which can be zero-cross aligned. The IC also provides control of fine-resolution digital gain after the ADC, further aligned with the analog gain change. The advantages of such systems are smooth, click/pop-free gain control, and the best possible dynamic range by varying the analog gain at the very first stage of the signal path (i.e. the conditioning circuit). Challenges associated with such systems comprising externally switched analog gain is that such solutions can be expensive and complex to implement, requiring analog switches to switch different gain-setting resistors into such circuits.

Embodiments of the present disclosure, such as those described above, offer a lower-cost alternative in which a fixed-gain signal conditioning circuit (e.g. the fixed external gain stage 202) is provided with the controller 212 configured to control capacitor scaling of analog gain inside the IC. Thus, the PAD system 200 of FIG. 2 can be used to implement such gain control, enabling implementation of smooth, pop-free, fine-resolution input signal path gain control that provides a user experience similar to a continuously-variable microphone preamp, but with no gain switching required outside of the IC, and only slightly lower dynamic range than an external switched-gain mic preamp. Such a trade off may be of particular use in cost-sensitive, mid-performance audio ADC applications.

It will be appreciated that the PAD system 200 described above avoids the need for external adjustable gain stages, such as the PAD gain stage 102. Implementing adjustable gain stages as switched resistor gain devices can be expensive and complex, with cost and complexity scaling proportionally to the number of gain steps.

Notwithstanding, a low-cost external switched-gain gain stage having only a very limited number of gain steps of large gain change size can be implemented which covers a wide range of gain whilst maintaining excellent DNR.

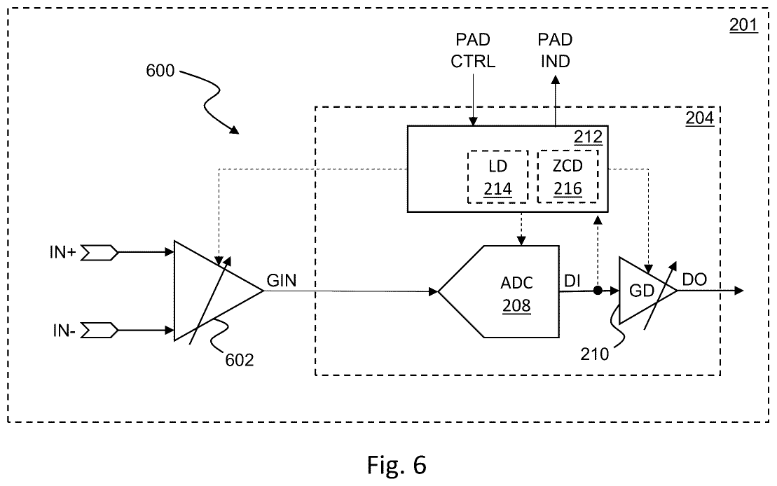

FIG. 6 is a schematic diagram of an example system 600 which is a variation of the system 200 shown in FIG. 2. The system 600 differs in that the internal analog gain stage 206 is omitted and external gain stage 602 (or pre-amplifier) is provided to generate the gain adjusted input signal GIN which is provided directly to the ADC 208. The ADC 208 may be controlled by the controller 212 to adjust gain applied by the ADC 208.

In this embodiment, the ADC 208 may implement an ADC capacitor ratio gain which provides intermediate analog gain steps of smaller size than the analog gain steps of the switched resistor external gain stage 602. Additionally, or alternatively, the gain of the ADC 208 may be altered by changing a feedback DAC reference. In such an example, the ADC 208 may be implemented as a discrete-time switched capacitor ADC. Alternatively, the ADC 208 may be implemented using any known continuous-time architecture. In such cases, gain may be varied with variation of input resistance of the ADC 208, or by altering a feedback DAC reference, as is known in the art.

Digital gain GD of the digital gain stage 210 may then provide very fine gain control resolution. The external gain stage 102 may be controlled by the controller 212.

The external gain stage 602 may be implemented using any known circuit topology. For example, the external gain stage 602 may be implemented as a switched-resistor external gain stage 602. Alternatively, the external gain stage 602 may be implemented using a discrete bipolar front-end differential amplifier and gain set with a single switched resistor stack between positive and negative sides of the differential amplifier. In any case, the external gain stage 602 may be configured to have two or more gain settings. In the simplest arrangement, two gain settings may be provided (to allow simple PAD on/off status). In more complex arrangements, more than two gain settings may be provided. The operation of the external gain stage 602 may be coordinated, e.g. by the controller 212 with gain update commands to allow for the external gain stage 602 to implement both a PAD feature and an external gain stage.

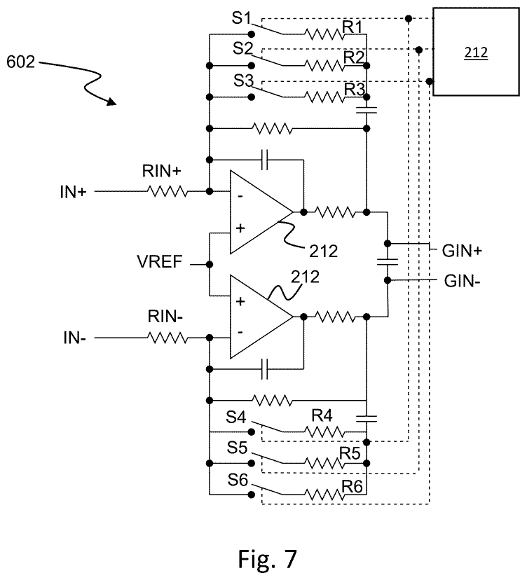

FIG. 7 is a schematic diagram of a known example implementation of the external gain stage 602 implemented as a switched-resistor amplifier.

In this example, the external gain stage 602 comprises a first op-amp 702 and a second op-amp 704. The first op-amp 702 comprises a plurality of resistors R1, R2, R3 switchable via respective switches S1, S2, S3 into the feedback path of the first op-amp 702. Likewise, the second op-amp 704 comprises a plurality of resistors R4, R5, R6 switchable via respective switches S4, S5, S6 into the feedback path of the second op-amp 704. The switches S1, S2, S3, S4, S5, S6 are controlled by the controller 212 to adjust the gain of each op-amp 702, 704 to adjust the gain of the external gain stage 602 in step changes.

It will be appreciated that provision of the external gain stage 602, such as that depicted in FIG. 7 may result in significant DNR drop between gain steps, particularly when gain steps are large.

Thus, in a further implementation external switched resistor gain selection may be combined with internal analog gain adjustment.

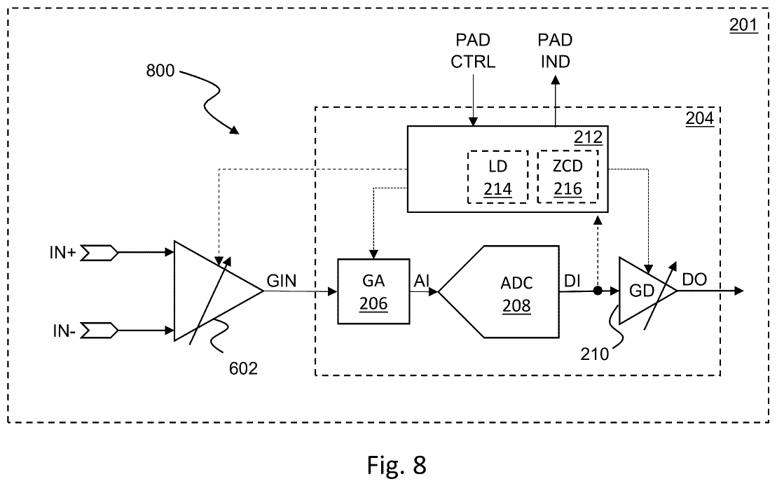

FIG. 8 is a schematic diagram of an example system 800 which is a variation of the system 200 shown in FIG. 2. The system 800 varies in that the switched resistor external gain stage 602 of FIG. 7 is provided on the front end of the IC 204. Thus, the system 800 comprises the external gain stage 602, the internal analog gain stage 206, and the digital gain stage 210. Such a system can provide fine gain steps and optimize ADC DNR performance, at lower cost than implementing more gain steps in the external switched resistor gain stage 602.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote-control device, a home automation controller or a domestic appliance including a domestic temperature or lighting control system, a toy, a machine such as a robot, an audio player, a video player, or a mobile telephone for example a smartphone, a mixing device or console (such as an audio mixing device or audio mixing console), an audio recording device, a paging station, an audio input device for use with a computer, a musical instrument, an audio effects processor, an audio surveillance device, a voice capture device, an audio broadcast device, a sound reinforcement device, a wireless electrical musical instrument interface, a wireless microphone, a microphone with digital output, an ultrasound sensing device, an ultrasound recording device, or a sonar device.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. An integrated circuit (IC), comprising:
a first gain stage configured to apply a first gain to a first signal to generate a first gain adjusted signal;
a first converter configured to convert the first gain adjusted signal to a first converted signal;
a second gain stage configured to apply a second gain to the first converted signal to generate a second gain adjusted signal; and
a controller configured to coordinate changes in a first gain of the first gain stage and a second gain of the second gain stage to prevent transients in the second gain adjusted signal.

2. The IC of claim 1, wherein the first signal comprises an analog signal, the first converter comprises an analog-to-digital converter (ADC), and the first converted signal comprises a digital signal.

3. The IC of claim 2, wherein the ADC comprises a switch-capacitor array, wherein the first gain stage comprises a plurality of switched capacitors, the controller configured to control the switched capacitors to change the first gain.

4. The IC of claim 1, wherein the controller is configured to change the first gain and the second gain in response to a control signal to implement a total gain.

5. The IC of claim 4, wherein the controller is configured to output a control signal via a pin of the IC to adjust an external gain of an external gain stage contributing to the total gain, wherein the controller is configured to coordinate changes in the external gain to prevent transients in the second gain adjusted signal.

6. The IC of claim 1, wherein the control circuitry comprises zero-cross detection circuitry configured to monitor the first signal, the first gain adjusted signal, the first converted signal, or the second gain adjusted signal for a zero-crossing and time-align changes in the first and second gain with the zero-crossing.

7. The IC of claim 1, wherein the controller is further configured to output an external gain control signal to a control pin of the IC, the external gain control signal coordinated with changes in the first and second gains.

8. The IC of claim 1, wherein the controller is configured to coordinate the changes in the first and second gains using hysteretic control.

9. The IC of claim 1, wherein the controller is configured to monitor a signal level of the first converted signal and adjust the first and/or second gain if the signal level exceeds a predetermined threshold level.

10. The IC of claim 9, wherein the controller is configured to reverse the adjustment in the first and/or second gain in response to one or more of the following:
a. expiry of a predetermined time period;
b. an external reset command.

11. The IC of claim 9, wherein the controller is configured to adjust the first and/or second gain to prevent saturation of the converter whilst maximizing dynamic range in the converter.

12. A system comprising:
The IC of claim 1; and
a pre-gain stage configured to apply an attenuation to an input signal to generate the first signal.

13. (canceled)

14. An integrated circuit (IC) comprising:
an input for receive an input signal;
a converter configured to convert the input signal to a digital signal;
a digital gain stage configured to apply a digital gain to the digital signal to generate an output signal; and
a controller configured to receive a passive attenuation device (PAD) control signal and adjust operation of the digital gain stage in dependence on the PAD control signal.

15. The IC of claim 14, wherein the controller is configured to receive a gain control signal separate from the PAD control signal and adjust operation of the digital gain stage based on the PAD control signal and the gain control signal.

16. The IC of claim 15, wherein the IC further comprises:
an analog gain stage configured to apply an analog gain to the input signal before conversion by the converter.

17. (canceled)

18. The IC of claim 16, wherein the analog gain is variable, and wherein the controller is configured to adjust operation of the analog gain stage based on the PAD control signal and the gain control signal.

19. The IC of claim 14, wherein the controller is configured to output a PAD output signal to an output pin of the IC based on a PAD control signal received at the controller, the PAD output signal for control of an external passive attenuation device coupled to the input.

20. The IC of claim 19, wherein the controller is configured to coordinate output of the output signal with changes in the digital gain to prevent transients in the output signal.

21. The IC of claim 14, wherein the controller comprises zero-cross detection circuitry for detecting one or more zero-cross events in the signal chain, the controller configured to coordinate changes in the digital gain with one of the one or more detected zero-cross events.

22. The IC of claim 14, wherein the controller is configured to mute the output signal when changing the digital gain applied to the digital signal.

23. (canceled)

24. An audio system, comprising:
an analog input for receiving an analog input signal;
a discrete analog gain stage configured to apply a first analog gain to the first analog input signal to generate a first amplified signal; and
an IC according to claim 14, the IC configured to receive the first amplified signal as the input signal.

25. (canceled)

28. An electronic device comprising an IC according to claim 1, wherein the electronic device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console for a VR or AR device, a mobile telephone, a portable audio player or other portable device, a mixing console, an audio mixing device, an audio recording device, a paging station, an audio input device for use with a computer, a musical instrument, an audio effects processor, an audio surveillance device, a voice capture device, an audio broadcast device, a sound reinforcement device, a wireless electrical musical instrument interface, a wireless microphone, a microphone with digital output, an ultrasound sensing device, an ultrasound recording device, or a sonar device.
